(19) United States
(12) Patent Application Publication
(10) Pub. No.: US 2017/0366139 A1
(43) Pub. Date: Dec. 21, 2017

(54) ARRANGEMENT FOR RADIO FREQUENCY HIGH POWER GENERATION

(71) Applicant: LIMITED LIABILITY COMPANY "SIEMENS", Moscow (RU)

(72) Inventors: Evgeny Ivanov, Moscow (RU); Andrey Krasnov, Moscow (RU); Ilya Rezanov, Moscow (RU)

(21) Appl. No.: 15/540,414

(22) PCT Filed: Dec. 29, 2014
(86) PCT No.: PCT/RU2014/001001

§ 371 Date: Jun. 28, 2017

(51) Int. Cl. H03F 1/02; H03F 1/56; H03F 3/20; H03F 3/60; H03F 3/72; H03F 3/189

(52) U.S. Cl. CPC H03F 1/0205; H03F 3/72; H03F 3/189; H03F 3/20; H03F 3/605; H03F 1/56; H03F 2200/417; H03F 2200/423; H03F 2200/451; H03F 2203/7221

(57) ABSTRACT

Systems are provided for RF high power generation. An arrangement includes an RF power combiner, at least one RF power amplifier, a switch, a control unit, and a transmission line. The RF power combiner has at least one RF input and at least one RF output. The RF power amplifier is electrically connected to the RF input via the transmission line. The switch is included in the transmission line. The switch is configured to control, by a switching action, transmission of a RF signal from the RF power amplifier to the RF input via the transmission line. The control unit is electrically connected to the switch. The control unit is configured to control the switching action of the switch. The control unit is electrically connected to the switch via the same transmission line.

### CROSS REFERENCE TO RELATED APPLICATION

The present patent document is a §371 nationalization of PCT Application Serial Number PCT/RU2014/001001, filed Dec. 29, 2014, designating the United States, which is hereby incorporated by reference.

### FIELD

Embodiments relate to an arrangement for RF high power generation.

### BACKGROUND

RF power combiners are devices used in radio technology when there is a requirement of combining radio frequency (RF) power or RF signals. RF power combiners receive a plurality of RF inputs and transform an impedance of the received RF inputs to impedance of a single transmission line as output. One way to generate high RF power is to use a number of RF power amplifiers with a common (e.g., single) RF power combiner. RF power from the RF power amplifiers is fed to the RF power combiner. The RF power amplifiers are connected via transmission lines to the common RF power combiner. The RF signals from the RF power amplifier are aggregated in the RF power combiner to yield a high RF power. Coaxial cables and/or strip-lines may be used as transmission lines connecting each of the RF power amplifiers with the RF power combiner. The output power of RF power combiner is adjusted and optimized to obtain a desired output RF signal.

One way of adjustment and/or optimization of the output RF power is by controlling the RF signals from the RF power amplifiers feeding the RF power combiner. For example, if there is a requirement of lowering power of the RF output of the RF power combiner, one or more of the RF power amplifiers may be stopped from providing the input to the RF power combiner. Alternatively, for example, if there is a requirement of increasing power of the RF output of the RF power combiner, one or more of the RF power amplifiers may be switched on for providing the input to the RF power combiner. To achieve control on the RF power amplifiers (e.g., to control the RF power amplifiers such that the RF signal from only the desired RF amplifiers is fed into the RF power combiner), each transmission line connecting a given RF amplifier to the RF power combiner is equipped with a switch that may be positioned at each of the RF power inputs of the RF power combiner. Each switch allows or disallows a given RF power amplifier from providing an RF signal to the RF power combiner. Each switch may be controlled by a separate control unit. The control unit induces the switching action (e.g., turns the switch ‘ON’ or ‘OFF’). The control unit is connected to the switch by separate electrical connectors. Information to the control unit to induce the switch may come from a central control system.

The high power RF amplifier/generator system may include a plurality of RF power amplifiers each with a separate switch, and each switch may include a control unit connected with the switch with separate electrical connectors. A lot of wires or electrical connectors are provided for connecting the control unit to the switch. The entire layout or arrangement is complex and cost intensive.

### SUMMARY AND DESCRIPTION

The scope of the present invention is defined solely by the appended claims and is not affected to any degree by the statements within this summary. The present embodiments may obviate one or more of the drawbacks or limitations in the related art.

Embodiments provide a simple and cost effective arrangement for RF high power generation.

In an embodiment, an arrangement for RF high power generation is presented. The arrangement includes an RF power combiner, at least one RF power amplifier, a switch, a control unit, and a transmission line. The RF power combiner includes at least one RF input and at least one RF output. The RF power amplifier is electrically connected to the RF input via the transmission line. The switch is included in the transmission line. The switch is configured to perform a switching action. The switch is configured to control, by the switching action, transmission of a RF signal from the RF power amplifier to the RF input via the transmission line. The control unit is electrically connected to the switch. The control unit is configured to control the switching action of the switch. The control unit is electrically connected to the switch via the same transmission line. Additional connections or transmission lines between the control unit and the switch are obviated. The same transmission line conducts the RF signal from the RF power amplifier to the switch and also simultaneously conducts a control signal (e.g., a DC signal from the control unit to the switch). The control signal induces the switching action in the switch, resulting in a simple arrangement of the RF high power generation. Since fewer elements are required (e.g., only one and the same transmission line between the RF power amplifier and the switch and between the control unit and the switch), the complexity of the circuit is reduced. This further results in cost effectiveness and possibility of easy maintenance.

In an embodiment, the transmission line is a coaxial cable. The coaxial cable is a simple and efficient way for establishing the transmission line that conducts the RF signal from the RF power amplifier to the RF power combiner and also simultaneously conducts a control signal (e.g., a DC signal from the control unit to the switch).

In another embodiment, the RF power amplifier and the control unit form an RF module. The RF module is a single unit. The RF module may be in the form of a box or casing having the RF power amplifier and the control unit. The RF module provides for simple and easy integration in an RF tract.

In another embodiment, the arrangement includes an RF choke that is connected between the control unit and the RF power amplifier. The RF choke electrically isolates the control unit from the RF signal coming from the RF power amplifier, when the RF power amplifier is in use or has been used to generate the RF signal. The control unit is thus not affected by the RF signal.

In another embodiment, the arrangement includes a first DC-blocking capacitor that is connected between the RF power amplifier and the control unit. The first DC-blocking capacitor electrically isolates the RF power amplifier from a DC signal coming from the control unit, when the control unit is in use or has been used to generate the DC signal. The RF power amplifier is thus not affected by the DC signal.

In another embodiment, the arrangement includes a second DC-blocking capacitor that is connected between the switch and the RF power combiner. The second DC-blocking capacitor electrically isolates the RF power combiner from the DC signal coming from the control unit, when the control unit is in use or has been used to generate the DC signal. The RF power combiner is thus not affected by the DC signal.

In another embodiment, the control unit includes a stabilized DC source and/or a DC voltage source.

In another embodiment, the switch includes a PIN diode. The PIN diode is configured to switch between ‘ON’ mode and ‘OFF’ mode, in which the RF signal is allowed or disallowed, respectively, to flow across the switch. The PIN diode is an efficient switch for RF applications.

In another embodiment, the switch includes a transistor. The transistor is configured to switch between ‘ON’ mode and ‘OFF’ mode, in which the RF signal is allowed or disallowed, respectively, to flow across the switch. The transistor is an efficient switch for RF applications.

In another embodiment, the switch is connected in series with respect to the transmission line and the RF power combiner.

In another embodiment, the switch is connected in parallel with respect to the transmission line and the RF power combiner.

### BRIEF DESCRIPTION OF THE FIGURES

FIG. 1 depicts a layout for an RF power amplifier and an RF power combiner.

FIG. 2 depicts an arraignment for RF high power generation according to an embodiment.

### DETAILED DESCRIPTION

Hereinafter, above-mentioned and other features of the present technique are described in detail. Various embodiments are described with reference to the drawing, where like reference numerals are used to refer to like elements throughout. In the following description, for purpose of explanation, numerous specific details are set forth in order to provide a thorough understanding of one or more embodiments. The illustrated embodiments are intended to explain, and not to limit, the invention. Such embodiments may be practiced without these specific details.

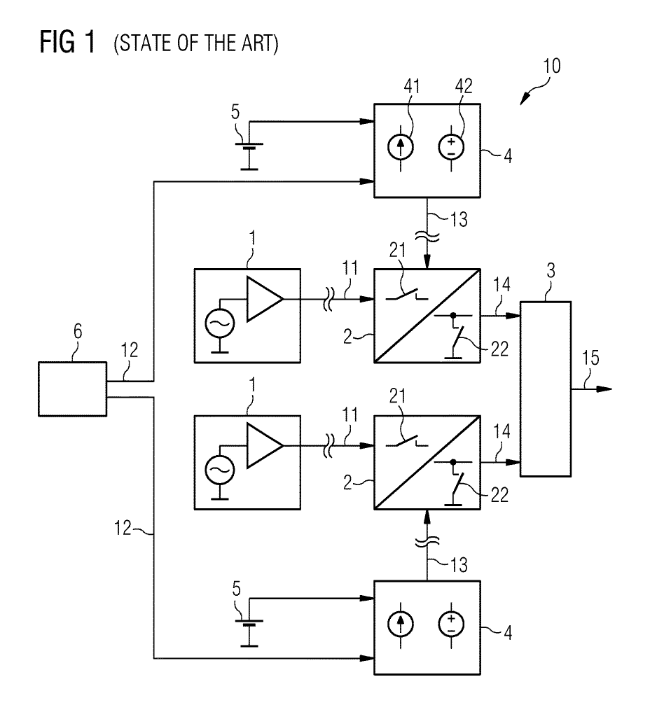

FIG. 1 depicts a layout 10 including RF power amplifiers 1 and a RF power combiner 3.

In the layout 10, the RF power combiner 3 includes RF inputs 14 and a RF output 15. Each of the RF input 14 of the RF power combiner 3 is connected by a transmission line 11 to the RF power amplifier 1. An RF signal or RF power from the RF power amplifiers 1 is fed to the RF input 14 of the RF power combiner 3 via the transmission line 11. To control the feed from the RF power amplifiers 1 (e.g., to control the RF power amplifiers 1 such that RF signal from only the desired RF amplifiers 1 is fed into the RF power combiner 3), each transmission line 11 connecting a given RF amplifier 1 to the RF power combiner 3 is equipped with a switch 2. The switch 2 may be positioned at the respective RF power input 14 to which the transmission line 11 connects. Each switch 2, by a switching action, allows or disallows a given RF power amplifier 1 from providing an RF signal to the RF power combiner 3. Each switch 2 is controlled by a separate control unit 4. The control unit 4 induces the switching action (e.g., turns the switch ‘ON’ or ‘OFF’). The control unit 4 is connected to the switch 2 by separate electrical connectors 13. Information to the control unit 4 to induce the switch 2 to be in the ‘ON’ or the ‘OFF’ state is provided from a central control system 6 via the connectors 12.

Although only two power amplifiers 1, respective connections, switches 2, and control units 4 are depicted in FIG. 1, the high power RF amplifier/generator systems may include a plurality of the RF power amplifiers 1 each with a separate switch 2. Each switch 2 has a separate control unit 4 connected with the switch 2 via separate electrical connectors 13.

The control unit 4 controls position of the switch 2 by applying current or voltage to the switch 2 and switching the switch 2 to conductive and non-conductive states accordingly. The control unit 4 may include a stabilized DC source 41 and/or a DC voltage source 42 along with an optional microprocessor (not shown) to control the DC current or the DC voltage provided from the control unit 4 to the switch 2. A DC power supply 5 is used to provide power for the control unit 4. To connect one RF power amplifier 1 to one RF input 14 of the RF power combiner 3, at least one transmission line 11 is to be provided to connect the RF power amplifier 1 to the RF input 14 and at least one electrical connector 13 is to be provided to connect the control unit 4 to the switch 2 that controls the transmission line 11.

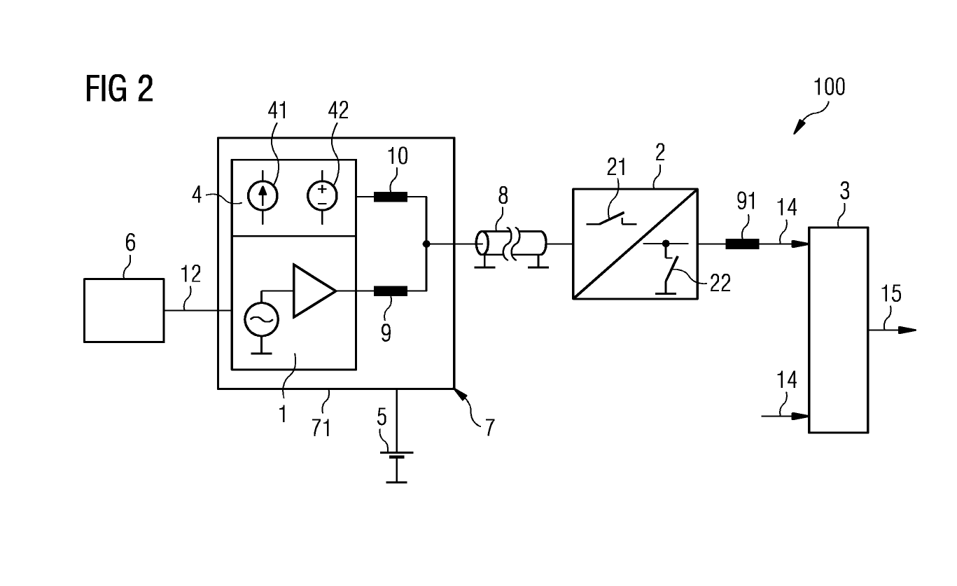

FIG. 2 depicts one embodiment of an arrangement 100 including an RF power combiner 3, at least one RF power amplifier 1, a switch 2, a control unit 4, and a transmission line 8.

The RF power combiner 3 is a RF power combining circuit that accepts multiple input RF signals and deliver a single RF output signal. The RF power combiner 3 includes multiple RF inputs 14 and at least one RF output 15. The RF power combiner 3 receives RF power through the plurality of RF inputs 14 and transforms the impedance of the received RF power to impedance of a resultant single output. The resultant single output exits the RF power combiner 3 via a single RF output 15. The RF power combiner 3 may be of various types (e.g., zero-degree RF power combiners) and may have any technical specification.

The RF power amplifier 1 is electrically connected to the RF input 14 via the transmission line 8. The transmission line 8 may be, but not limited to, a coaxial cable.

The switch 2 or the RF switch 2 may be, but not limited to, a transistor and/or a PIN diode. The switch 2 is configured to perform a switching action. The switch is configured to control, by the switching action, transmission of a RF signal from the RF power amplifier 1 to the RF input 14 passed via the transmission line 8. The control unit 4 is electrically connected to the switch 2. The control unit 4 is configured to control the switching action of the switch 2. The control unit 4 may include a stabilized DC source 41 and/or a DC voltage source 42 along with an optional microprocessor (not depicted) to control the DC current or the DC voltage provided from the control unit 4 to the switch 2. A DC power supply 5 provides power for the control unit 4. The control unit 4 is electrically connected to the switch 2 via the same transmission line 8. Electrical connectors 13, as depicted in FIGS. 1, between the control unit 4 and the switch 2 are obviated. In the arrangement 100, the same transmission line 8 conducts the RF signal from the RF power amplifier 1 to the RF input 14 and also simultaneously conducts a control signal (e.g., a DC signal from the control unit 4 to the switch 2). The control signal induces the switching action in the switch 2.

In one embodiment, the switch 2 is connected in series with respect to the transmission line 8, the RF power combiner 3, and the RF power amplifier 1. In FIG. 2, reference numeral 21 schematically depicts the switch 2 in series connection. The switch 2 may be positioned at the RF input 14. Alternatively, in another embodiment, the switch is connected in parallel with respect to the transmission line 8 and the RF power combiner 3. In FIG. 2, reference numeral 22 schematically depicts the switch 2 in parallel connection.

When the switch 2 is included in the Arrangement 100 connected in series with the transmission line 8, in ‘ON’ mode, the switch 2 (e.g., the PIN diode 2) allows flow of the RF signal via the transmission line 8 from the RF power amplifier 1 to the RF power combiner 3, and in ‘OFF’ mode, the PIN diode 2 disallows flow of the RF signal via the transmission line 8 from the RF power amplifier 1 to the RF power combiner 3. The control unit 4 controls position of the switch 2 by applying current or voltage to the switch 2, and transforming the switch 2 to conductive or non-conductive states accordingly.

The switch 2 may also be operated in parallel connection schematic. When connected in parallel, for example, the switch 2 may be connected to provide a short circuit to the RF signal coming from the RF power amplifier 1, and when the switch is ‘ON’ or ‘CLOSED’, the RF signal from the RF power amplifier 1 is routed through the switch 2 and not towards the RF power combiner 3. When the switch is ‘OFF’ or ‘OPEN’, the RF signal from the RF power amplifier 1 is not routed through the switch and routed towards the RF power combiner 3. The switch 2 may be connected in the arrangement 100 in different circuit topologies (e.g., the control signal to the switch 2 from the control unit 4 is provided by the same transmission line 8 via which the RF signal from the RF power amplifier 1 is provided to the RF input 14).

The arrangement 100 includes an RF choke 10 of FIG. 2 connected between the control unit 4 and the RF power amplifier 1. The RF choke 10 electrically isolates the control unit 4 from the RF signal coming from the RF power amplifier 1, when the RF power amplifier 1 is in use or has been used to generate the RF signal. The arrangement 100 includes a first DC-blocking capacitor 9 connected between the RF power amplifier 1 and the control unit 4. The first DC-blocking capacitor 9 electrically isolates the RF power amplifier 1 from a DC signal coming from the control unit 4, when the control unit 4 is in use or has been used to generate the DC signal. The DC signal coming from the control unit 4 includes the signal to control or induce the switch 2 (e.g., to transform the switch 2 between a conductive state and a non-conductive state or to maintain the switch 2 in the conductive or nonconductive state).

In one embodiment, the RF power amplifier 1 and the control unit 4 form a RF module 7. The RF module 7 is a single unit. The RF module 7 may be in form of a box 71 or casing having the RF power amplifier 1 and the control unit 4 positioned inside the box 71. Additionally, the RF choke 10 and the first DC-blocking capacitor may also be positioned inside the RF module 7. A DC power supply 5 is provided to the RF module 7. A central control system 6 provides information to the control unit 4.

The arrangement 100 may further include a second DC-blocking capacitor 91 connected between the switch 2 and the RF power combiner 3. The second DC-blocking capacitor 91 electrically isolates the RF power combiner 3 from the DC signal coming from the control unit 4 and through the switch 2, when the control unit 4 is in use or has been used to generate the DC signal.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. An arrangement for RF high power generation, the arrangement comprising:
a RF power combiner with an RF input and an RF output;
an RF power amplifier electrically connected to the RF input via a transmission line;
a switchcomprised in the transmission line, the switch configured to control, by a switching action, transmission of an RF signal from the RF power amplifier to the RF input via the transmission line; and
a control unit electrically connected to the switch, the control unit configured to control the switching action of the switch,
wherein the control unit is electrically connected to the switch with the transmission line.

2. The arrangement of claim 1, wherein the transmission line is a single coaxial cable.

3. The arrangement of claim 1, wherein the RF power amplifier and the control unit form a RF module, and
wherein the RF module is a single unit.

4. The arrangement of claim 1, further comprising:
a RF choke connected between the control unit and the RF power amplifier, the RF choke configured to electrically isolate the control unit from the RF signal from the RF power amplifier.

5. The arrangement of claim 1, further comprising:
a first DC-blocking capacitor connected between the RF power amplifier and the control unit and configured to electrically isolate the RF power amplifier from a DC signal from the control unit.

6. The arrangement of claim 5, further comprising:
a second DC-blocking capacitor connected between the switch and the RF power combiner and configured to electrically isolate the RF power combiner from the DC signal from the control unit.

7. The arrangement of claim 1, wherein the control unit comprises a stabilized DC source, a DC voltage source, or a combination thereof.

8. The arrangement of claim 1, wherein the switch comprises a PIN diode.

9. The arrangement of claim 1, wherein the switch comprises a transistor.

10. The arrangement of claim 1, wherein the switch is connected in series with respect to the transmission line and the RF power combiner.

11. The arrangement of claim 2, wherein the switch is connected in parallel with respect to the transmission line and the RF power combiner.

12. The arrangement of claim 2, wherein the RF power amplifier and the control unit form a RF module, and
wherein the RF module is a single unit.

13. The arrangement of claim 2, further comprising:
an RF choke connected between the control unit and the RF power amplifier, the RF choke configured to electrically isolate the control unit from the RF signal from the RF power amplifier.

14. The arrangement of claim 2, further comprising:
a DC-blocking capacitor connected between the RF power amplifier and the control unit and configured to electrically isolate the RF power amplifier from a DC signal from the control unit.

15. The arrangement of claim 1, further comprising:
a DC-blocking capacitor connected between the at and the RF power combiner and configured to electrically isolate the RF power combiner from the DC signal from the control unit.

16. The arrangement of claim 2, wherein the control unit comprises a stabilized DC source, a DC voltage source, or a combination thereof.

17. The arrangement of claim 2, wherein the switch comprises a PIN diode.

18. The arrangement of claim 2, wherein the switch comprises a PIN diode.

19. The arrangement of claim 2, wherein the switch comprises a transistor.

20. The arrangement of claim 2, wherein the switch is connected in series with respect to the transmission line and the RF power combiner.
